(19) United States
(12) Patent Application Publication
(10) Pub. No.: US 2015/0131396 A1
(43) Pub. Date: May 14, 2015

(54) SEMICONDUCTOR MEMORY DEVICE WITH SWITCHES FOR SUSPENDING POWER SUPPLY

(71) Applicant: FUJITSU LIMITED, Kawasaki-shi (JP)

(72) Inventors: YASUHIDE SOSOGI, Kawasaki (JP); Gaku Ito, Kawasaki (JP)

(21) Appl. No.: 14/504,465

(22) Filed: Oct. 2, 2014

(30) Foreign Application Priority Data
Nov. 14, 2013 (JP) 2013-236157

(51) Int. Cl. G11C 5/14

(52) U.S. Cl. CPC G11C 5/148
USPC 365/227

(57) ABSTRACT

A method of making a semiconductor integrated circuit includes forming switches configured to suspend, on a way-specific basis, power supply to ways allocated to one or more RAM macros.

### CROSS-REFERENCE TO RELATED APPLICATIONS

The present application is based upon and claims the benefit of priority from the prior Japanese Patent Application No. 2013-236157 filed on Nov. 14, 2013, with the Japanese Patent Office, the entire contents of which are incorporated herein by reference.

### FIELD

The disclosures herein relate to a semiconductor memory device, a semiconductor integrated circuit and a method of making a semiconductor integrated circuit.

### BACKGROUND

In order to reduce power consumption in a semiconductor memory device, a method referred to as power gating may be used to suspend power supply to a particular portion of the memory (see Patent Documents 1 through 4, for example).

FIG. 1 is a drawing illustrating the configuration of a cache memory 100 that is an example of a semiconductor memory device having a plurality of RAM (random access memory) macros 150. The RAM macros 150 are circuit blocks each having the function of a RAM. Power gating may be performed separately for each of the RAM macros 150 as illustrated in FIG. 1. In this case, switches (e.g., transistors 10 illustrated in FIG. 1) for suspending power supply may need to be provided as many as the number of the RAM macros 150 in the cache memory 100.

[Patent Document 1] Japanese Laid-open Patent Publication No. 5-62496

[Patent Document 2] Japanese Laid-open Patent Publication No. 2003-178594

[Patent Document 3] Japanese Laid-open Patent Publication No. 8-45299

[Patent Document 4] Japanese Laid-open Patent Publication No. 11-25688

### SUMMARY

According to an aspect of the embodiment, a method of making a semiconductor integrated circuit includes forming switches configured to suspend, on a way-specific basis, power supply to ways allocated to one or more RAM macros.

According to an aspect of the embodiment, a semiconductor memory device includes one or more RAM macros, and switches configured to suspend, on a way-specific basis, power supply to ways allocated to the one or more RAM macros.

According to an aspect of the embodiment, a method of designing a semiconductor memory device includes selecting a word direction or a bit direction as a direction of placement in which ways allocated to one or more RAM macros are arranged next to one another, and setting switches configured to suspend, on a way-specific basis, power supply to the ways that are arranged next to one another in the direction of placement.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a drawing illustrating an example of a semiconductor memory device;

FIG. 2 is a flowchart illustrating an example of a method of making a semiconductor integrated circuit;

FIG. 3 is a drawing illustrating an example of way allocation;

FIG. 4 is a drawing illustrating an example of the configuration of ways of a cache memory;

FIG. 5 is a drawing illustrating an example of way allocation;

FIG. 6 is a drawing illustrating an example of the configuration of ways of a cache memory;

FIG. 7 is a drawing illustrating an example of the positional relationship between a cache memory and an interconnect line;

FIG. 8 is a drawing illustrating an example of a macro;

FIG. 9 is a flowchart illustrating an example of a way allocation step;

FIG. 10 is a table illustrating an example of way quantities in the word direction and word quantities;

FIG. 11 is a table illustrating an example of way quantities in the bit direction and bit quantities;

FIG. 12 is a drawing illustrating an example of a macro in which words are arranged next to each other in the word direction;

FIG. 13 is a drawing illustrating an example of a macro in which words are arranged next to each other in the bit direction;

FIG. 14 is a drawing illustrating an example of way allocation;

FIG. 15 is a drawing illustrating an example of the configuration of ways of a cache memory;

FIG. 16 is a drawing illustrating an example of the positional relationship between a cache memory and an interconnect line;

FIG. 17 is a drawing illustrating an example of switches for suspending power supply on a way-specific basis in the word direction;

FIG. 18 is a drawing illustrating an example of switches for suspending power supply on a way-specific basis in the bit direction;

FIG. 19 is a drawing illustrating an example of power supply being blocked on a way-specific basis in the word direction;

FIG. 20 is a drawing illustrating an example of power supply being blocked on a way-specific basis in the bit direction; and

FIG. 21 is a drawing illustrating an example of a semiconductor memory device and a semiconductor integrated circuit.

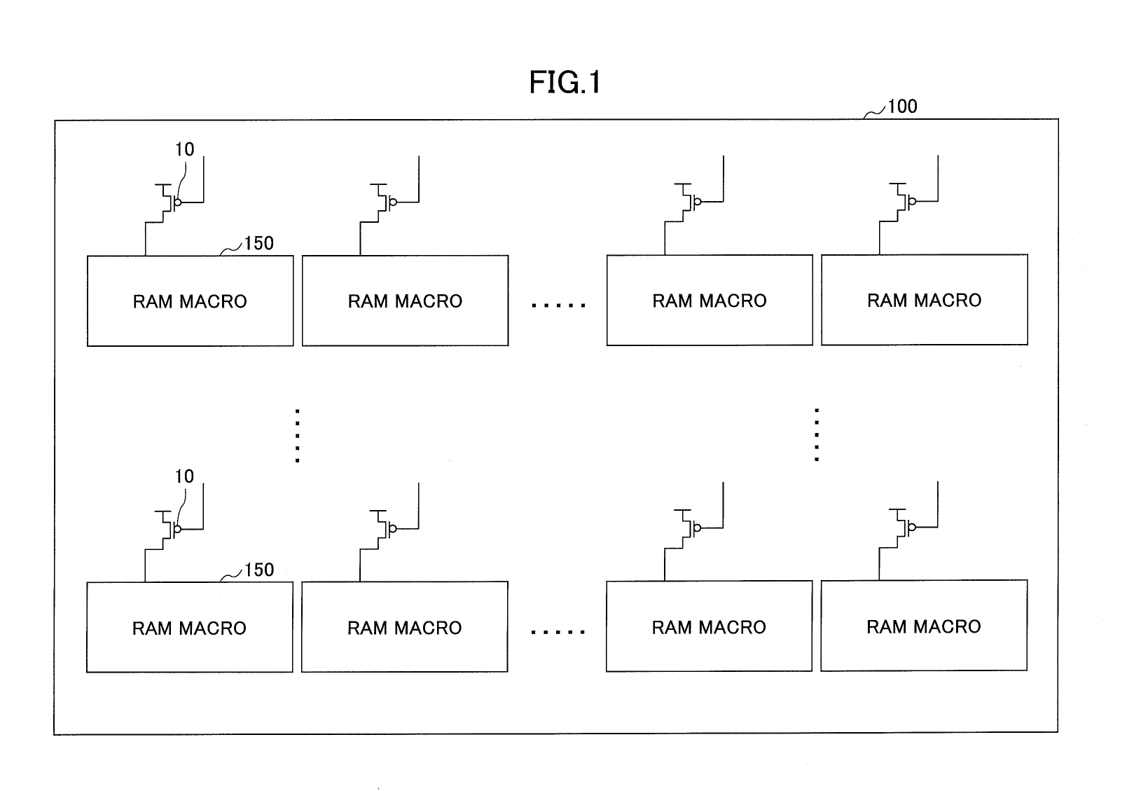

### DESCRIPTION OF EMBODIMENTS

In the following, embodiments of the present invention will be described with reference to the accompanying drawings.

### Method of Making Semiconductor Integrated Circuit

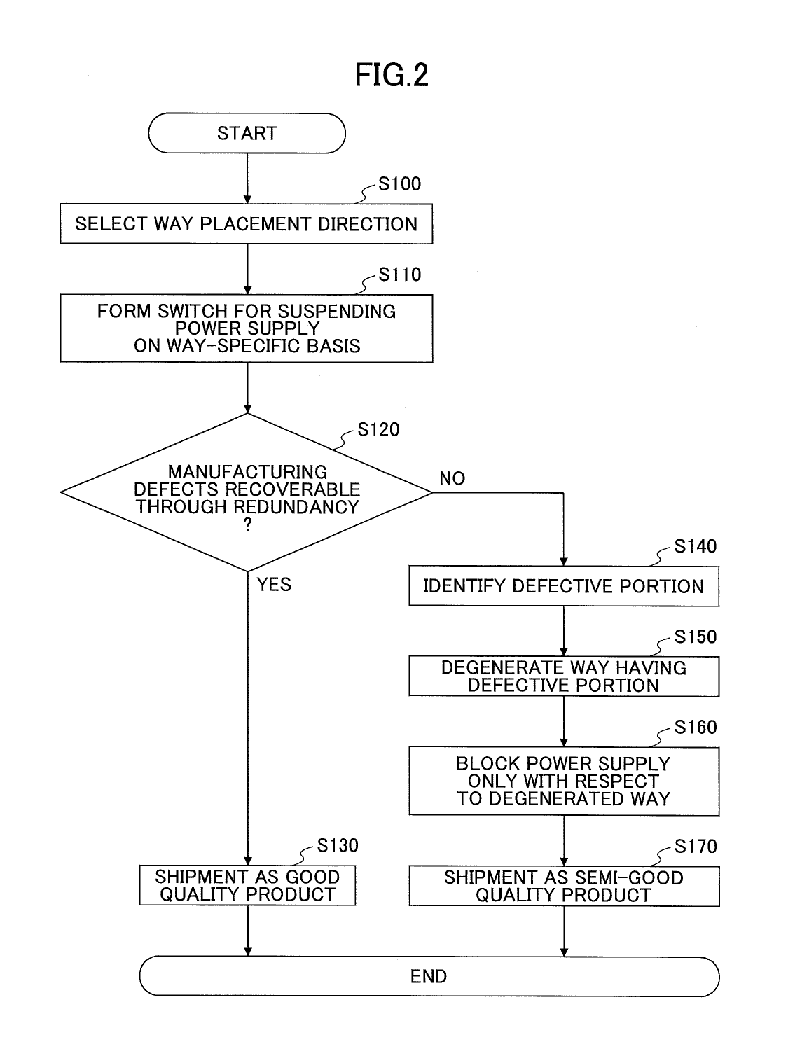

FIG. 2 is a flowchart illustrating an example of the method of making a chip having a cache memory. This chip is an example of a semiconductor integrated circuit. The cache memory is an example of a semiconductor memory device that is disposed between a main memory and a processor, and that holds data and addresses copied from the main memory that the processor will access. Examples of cache memories include a last level cache and a secondary cache (i.e., L2 cache).

Step S100 is an allocation step in which either a word direction or a bit direction is selected as a direction of way placement when ways are allocated to a RAM macro formed in a cache memory. The word direction refers to the direction in which words are sequentially arranged, and the bit direction refers to the direction in which bits are sequentially arranged. Further, the direction of way placement refers to the direction in which ways are arranged next to one another. The RAM macros 150 are circuit blocks each having the function of a RAM. Step S100 may be performed by a design support apparatus (e.g., computer) for aiding a designer to make a design, or may be performed by a designer.

A design support apparatus or a designer selects the bit direction as the direction of way placement when the implementation efficiency of the chip in the case of assigning the direction of way placement to the word direction is lower than the one obtained by assigning the direction of way placement to the bit direction. Conversely, a design support apparatus or a designer selects the word direction as the direction of way placement when the implementation efficiency of the chip in the case of assigning the direction of way placement to the bit direction is lower than the one obtained by assigning the direction of way placement to the word direction. Step S110 is performed after step S100.

Step S110 is a formation step in which switches are formed in the chip to suspend, on a way-specific basis, power supply to the ways arranged in the placement direction selected in step S100. Step S110 may be performed by a manufacturing apparatus that manufactures the chip.

Alternatively, step S110 may be a setting step in which a setting is made to form switches in the chip to suspend, on a way-specific basis, power supply to the ways arranged in the placement direction selected in step S100. In this case also, step S110 may be performed by a design support apparatus or a designer. Steps S100 and S110 are examples of design methods that are performed during the process of designing a chip.

With the provision of the formation step of step S110, a chip having a cache memory can be made that includes RAM macros and switches for suspending power supply on a way-specific basis with respect to the ways assigned to the RAM macros.

In the case of performing power gating on a RAM-macro-specific basis, switches for suspending power supply may need to be provided as many as the number of RAM macros implemented on a chip. On the other hand, the switches formed by the formation step of step S110 allows power gating to be performed on a way-specific basis. Because of this, it suffices to provide switches formed in step S110 only as many as the number of ways assigned to the cache memory (e.g., a few to more than a dozen ways). The number of switches can thus be significantly reduced compared to the case in which power gating is performed on a RAM-macro-specific basis.

Further, the ability to suspend power supply to the ways on a way-specific basis allows power to be suspended with respect to the ways that are not in use, and allows power to be supplied to the ways that are in use. In this manner, electric power consumed in the cache memory is efficiently supplied or suspended depending on the utilization of ways.

Step S120 is a check step that checks whether a manufacturing defect found during the inspection of the manufactured chip is recoverable through a redundancy system. Step S120 may be performed by a chip manufacturing apparatus.

In the manufacturing of semiconductor integrated circuits, defects due to manufacturing deficiency may easily occur. Memory cells in a cache memory are the smallest circuit on a processor die, and may thus end up having defects due to manufacturing deficiency In order to improve the production yield of cache memories, a cache memory may be provided with a redundancy replacement mechanism. Those chips in which the redundancy replacement mechanism cannot recover defects caused by manufacturing deficiency are treated as defective products. Some chips have no defects in the memory cells of the cache memory, and are treated as perfectly operable chips (satisfactory-quality products). Other chips may have defects in some of the memory cells of the cache memory, but may be treated as semi-satisfactory-quality products upon suspending the function of defective memory portions. Semi-satisfactory-quality products are supplied as processors in a different product line having a different rank than satisfactory-quality products.

Upon finding that redundancy-based recovery is effective in step S120, the manufacturing apparatus allows the manufactured chip to be shipped as a satisfactory-quality product in step S130. In the case of finding that redundancy-based recovery is not effective in step S120, the manufacturing apparatus identifies, in step S140, defective portions in the RAM macros based on information about defective portions obtained during the inspection of the manufactured chip.

Step S150 is a degeneration step that degenerates one or more ways having one or more defective portions therein, which are identified in the RAM macros through the inspection of the manufactured chip having undergone the formation step of step S110. The manufacturing apparatus degenerates the one or more ways having the one or more defective portions therein identified in step S140, thereby terminating the function of the memory portions included in the degenerated ways.

Step S160 is a blocking step that blocks power supply to the ways degenerated in step S150 by placing relevant switches formed in step S110 in the OFF state. By fixedly placing the relevant switches formed in step S110 in the OFF state, the manufacturing apparatus allows the chip, in which power supply to the ways degenerated in step S150 is blocked, to be shipped as a semi-satisfactory-quality product in step S170.

Degenerating a way alone may leave a risk of allowing a leak current to flow into the degenerated way. Blocking power supply to the degenerated way serves to reduce a leak current, thereby reducing power consumption in the cache memory and the chip. Such blocking also serves to prevent the occurrence of excess electric current due to shortcircuiting resulting from a manufacturing defect.

### Allocation of Ways in Word Direction

In the following, a description will be given of the case in which ways are arranged next to one another in the word direction in one-to-one correspondence with sub-arrays of the cache memory, which relates to the allocation step of step S100 illustrated in FIG. 2.

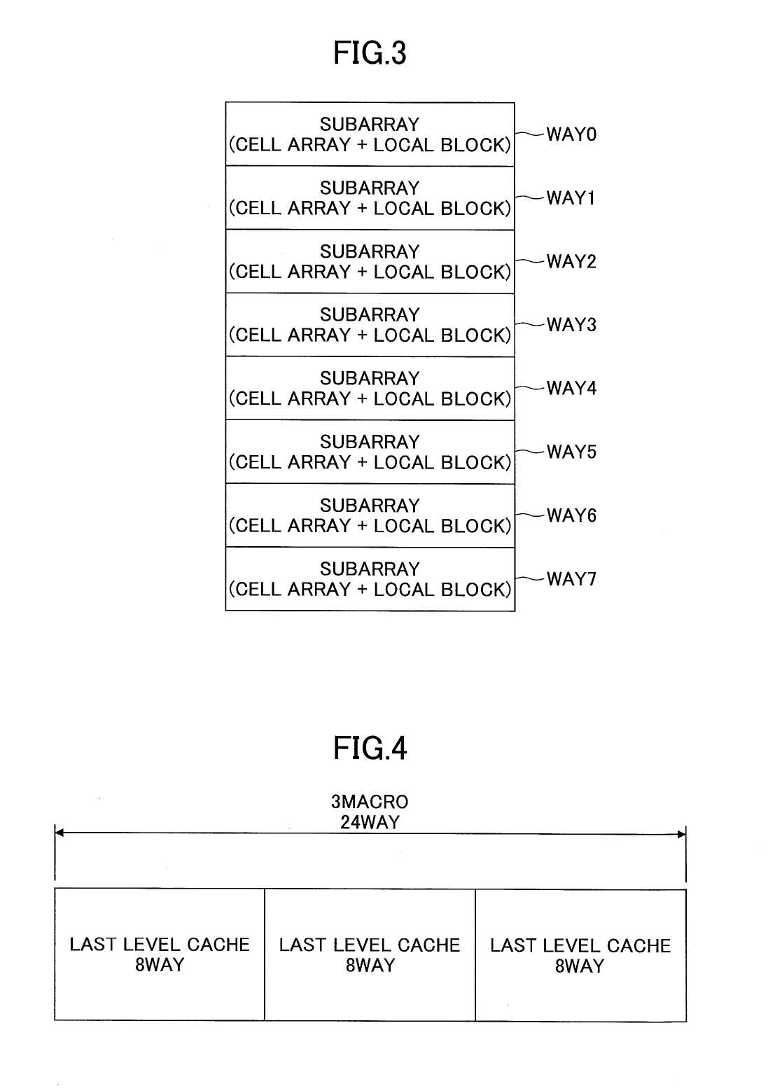

In an example illustrated in FIG. 3, one macro of the cache memory has 8 sub-arrays. In this case, arranging ways sequentially in the word direction in one-to-one correspondence with the sub-arrays results in one macro being constituted by 8 ways WAY0 through WAY7. A sub-array is a circuit block that includes a memory cell array and a local block. A chip having a 24-way configuration (i.e., a 24-way set associative cache memory) may be constituted by 3 macros as illustrated in FIG. 4 when one macro includes 8 ways.

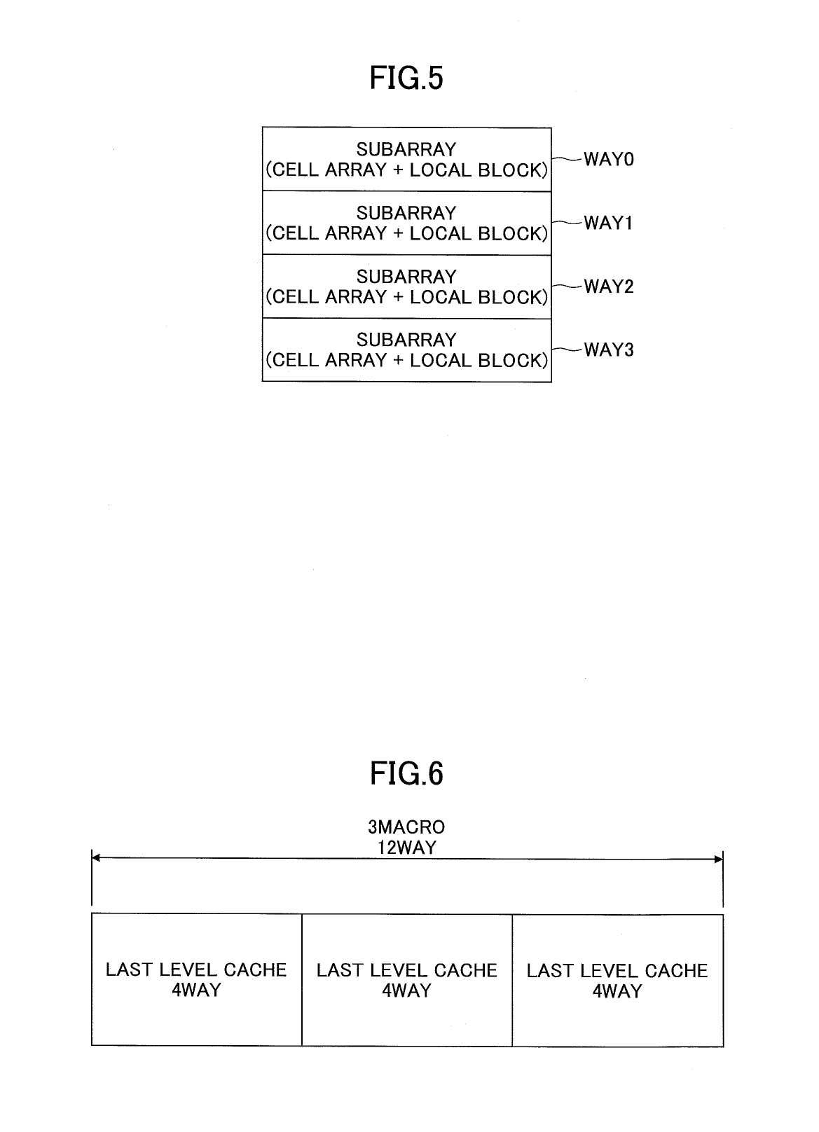

In an example illustrated in FIG. 5, one macro of the cache memory has 4 sub-arrays. In this case, arranging ways sequentially in the word direction in one-to-one correspondence with the sub-arrays results in one macro being constituted by 4 ways WAY0 through WAY3. A chip having a 12-way configuration (i.e., a 12-way set associative cache memory) may be constituted by 3 macros as illustrated in FIG. 6 when one macro includes 4 ways.

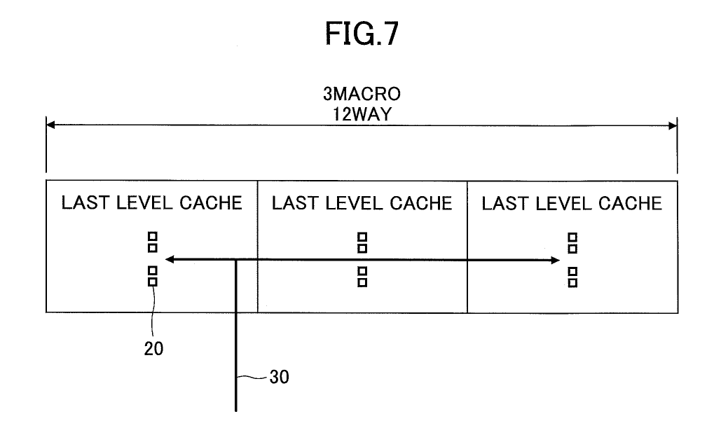

In the case of a way structure using three macros as described above, an interconnect line 30 coupled to cache memory terminals 20 may extend across one or more macro borders as illustrated in FIG. 7 (i.e., there may be a case in which the interconnect line 30 crossing a macro border is in existent). Such a structure may give rise to a problem in that an area immediately above the area where the macros reside cannot be used for placing a data bus, which may result in implementation efficiency being lowered. In such a case, a space may be created between macros in order to secure an area for placing a data bus, thereby resulting in an increase in chip size. Further, an increase in the number of repeaters for the purpose of avoiding a latency deterioration caused by making the interconnect line 30 go around the macros causes power consumption in the entire chip to be increased.

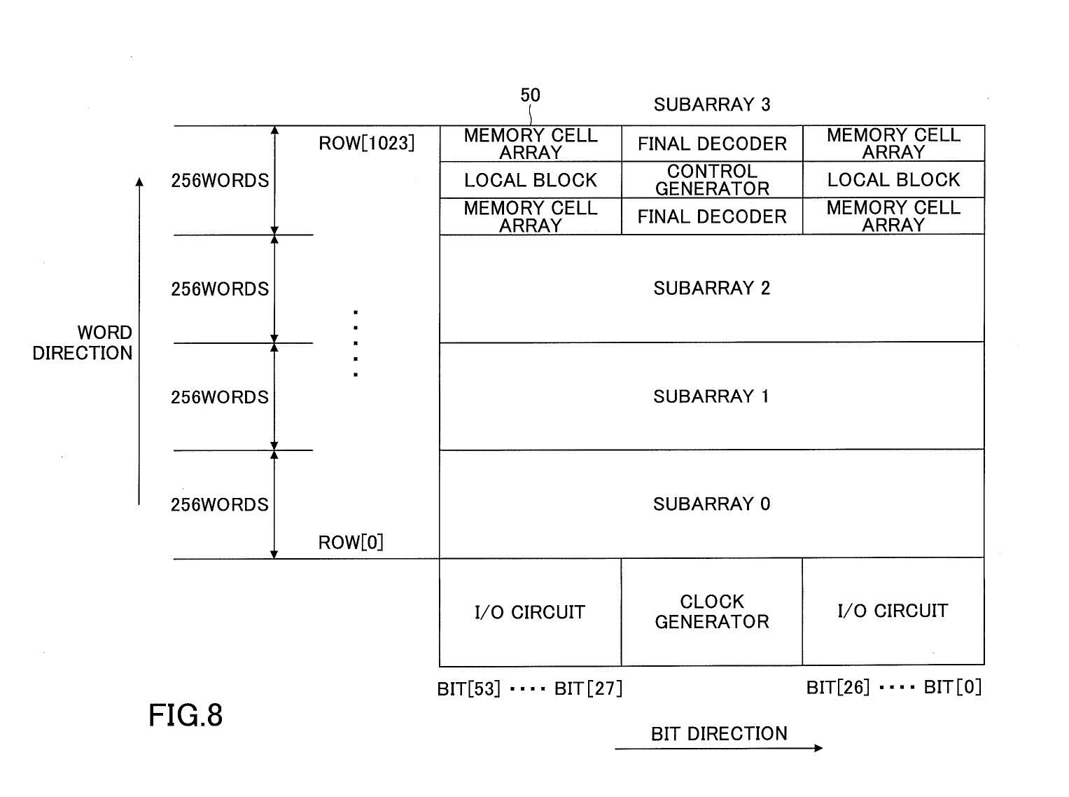

In the following, a description will be given of a method of selecting a direction of way placement performed in the way allocation step by use of a macro 50 illustrated in FIG. 8 as an example.

### Method of Selecting a Direction of Way Placement

FIG. 8 is a drawing illustrating an example of the configuration of the macro 50 (i.e., a schematic physical arrangement in the word direction and in the bit direction). The macro 50 is an example of a RAM macro constituted by 8K words (i.e., 8 columns×1024 words) by 54 bits In the case of the 8-column configuration, 1K words are sequentially arranged in the word direction.

The macro 50 includes 4 sub-arrays SUBARRAY0 through SUBARRAY3, periphery circuits (e.g., input and output circuit) for accessing the 4 sub-arrays, and a clock generator. Each sub-array includes memory cell arrays, local blocks, final decoders and a control generator.

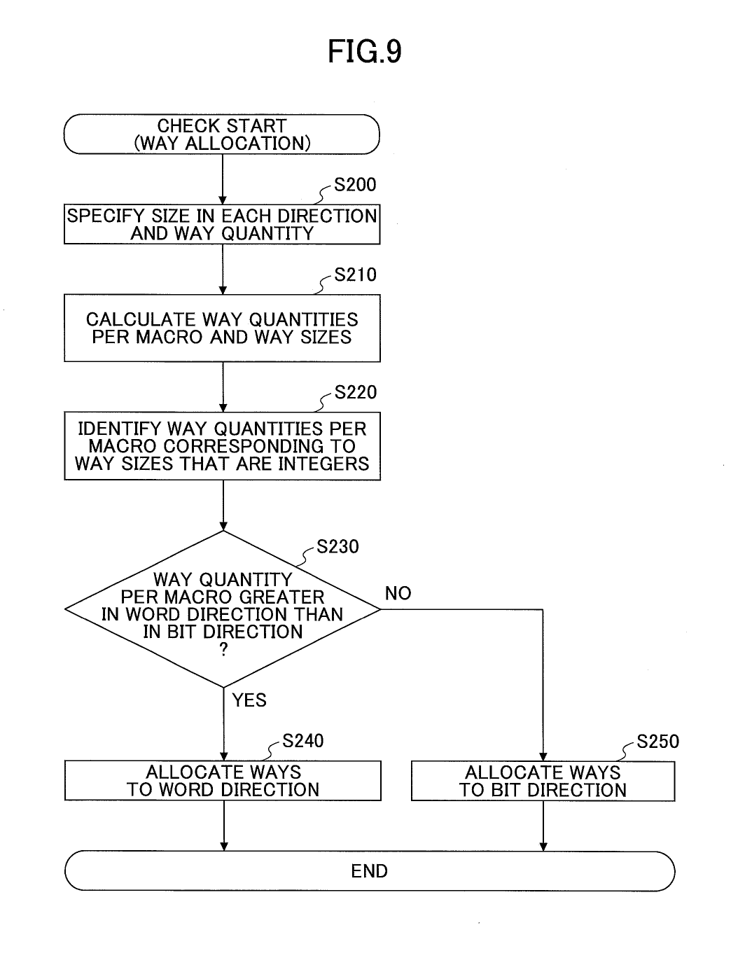

FIG. 9 is a flowchart illustrating an example of a method of allocating ways performed in the allocation step of step S100 illustrated in FIG. 2.

In step S200, a required specification (i.e., configuration requirements) of the chip is specified that includes the horizontal and vertical sizes of one macro and a total number of ways implemented on a chip. For example, the size of one macro is specified as 8K words×54 bits, and the provision of 12 ways in the entire chip is specified. When it is preferable to provide as few macro-crossing interconnect lines as possible, only one or two macros may be used to constitute the 12 ways.

In the case of a 12-way configuration for the entire chip being specified, the provision of a 12-way configuration by use of one macro means that one macro is designed to include 12 ways. The provision of a 12-way configuration by use of two macros means that each macro is designed to include 6 ways. The provision of a 12-way configuration by use of three macros means that each macro is designed to include 4 ways. In this manner, a design support apparatus or a designer calculates in step S210 the possible numbers of ways allocated to one macro based on the specified configuration requirements.

In step S210, the design support apparatus or the designer calculates the number of words per way and the number of bits per way with respect to each of the calculated possible numbers of ways allocated to one macro. Namely, the design support apparatus or the designer divides the total number of words arranged in the word direction (i.e., 8K words in this example) by a given one of the calculated possible numbers of ways allocated to one macro, thereby calculating the number of words per way. Similarly, the design support apparatus or the designer divides the total number of bits arranged in the bit direction (i.e., 54 bits in this example) by a given one of the calculated possible numbers of ways allocated to one macro, thereby calculating the number of bits per way.

It may be noted that both the number of words per way and the number of bits per way need to be integers to physically make sense.

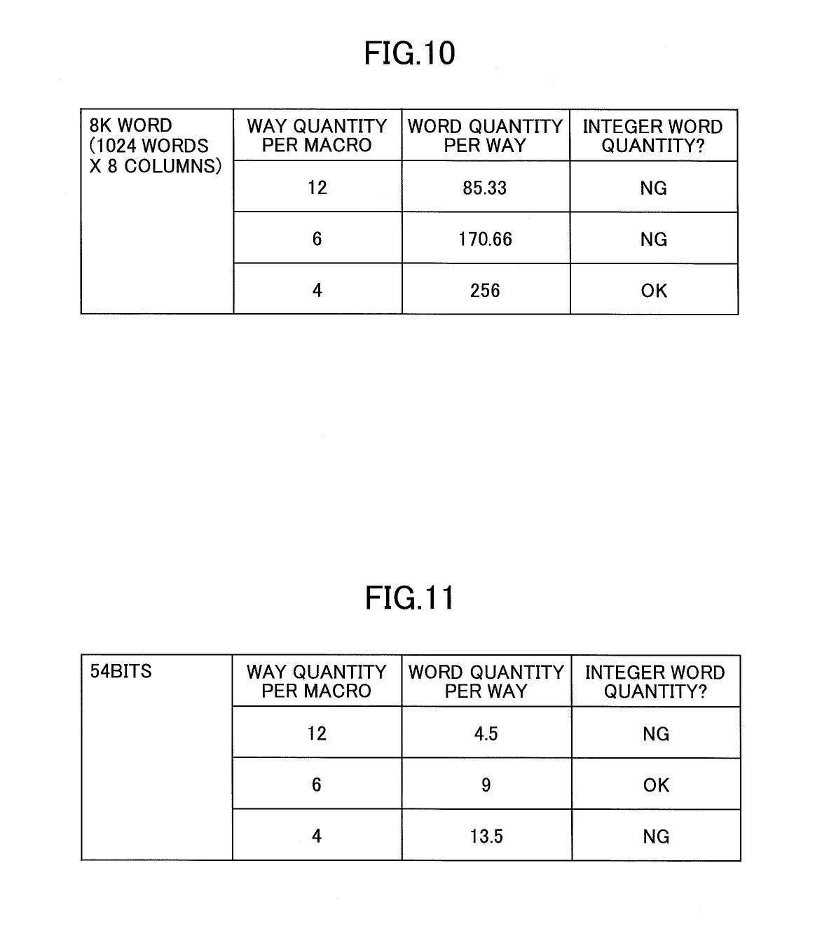

In the case of the 8K-word-by-54-bit configuration, in step S220, the design support apparatus or the designer selects “4” that is the number of ways that makes the number of words per way an integer, i.e., 256, and uses this selected quantity as a way quantity Nw that is assignable to one macro as illustrated in FIG. 10. In step S220 also, the design support apparatus or the designer selects “6” that is the number of ways that makes the number of bits per way an integer, i.e., 9, and uses this selected quantity as a way quantity Nb that is assignable to one macro as illustrated in FIG. 11.

Steps S200, S210 and S220 illustrated in FIG. 9 are examples of the steps that include a first calculation step of calculating the number of ways assignable to one RAM macro in the word direction and a second calculation step of calculating the number of ways assignable to one RAM macro in the bit direction.

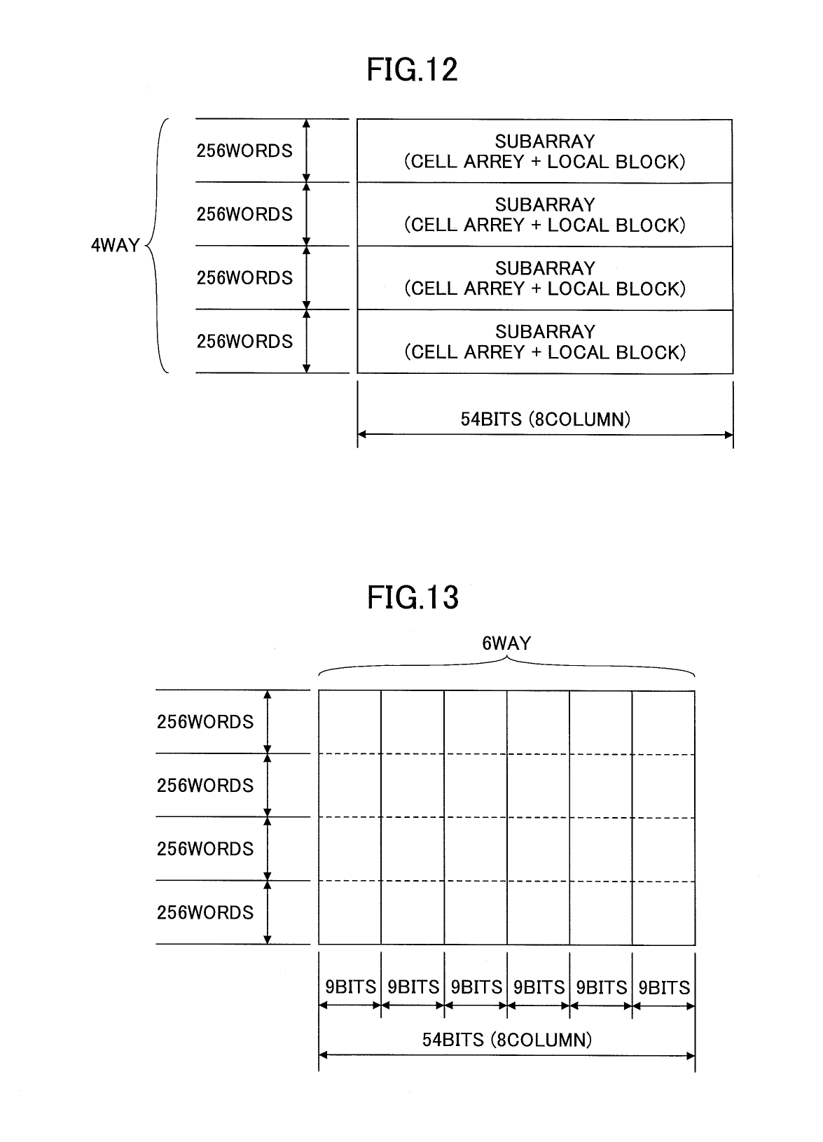

FIG. 12 is a drawing illustrating an example of a macro configuration used when 4 ways, i.e., as many ways as the way quantity Nw selected in step S220, are arranged next to one another in the word direction in one-to-one correspondence with the sub-arrays each having 256 words. FIG. 13 is a drawing illustrating an example of a macro configuration used when 6 ways, i.e., as many ways as the way quantity Nb selected in step S220, are arranged next to one another in the bit direction in units of 9 bits.

It may be noted that allocating ways in the direction corresponding to the greater one of the way quantities Nw and Nb selected in step S220 achieves a greater implementation efficiency than otherwise because the number of macros constituting the ways in the chip becomes smaller. This arrangement also reduces latency since available interconnect areas above the macros are broader. Further, spaces between macros for providing interconnect areas may be narrower or nonexistent, thereby achieving both an significant increase in implementation efficiency and a significant reduction in implementation cost.

In step S230 illustrated in FIG. 9, the design support apparatus or the designer compares the two way quantities Nw and Nb identified in step S220. In the case of Nw being greater than Nb, the design support apparatus or the designer selects the word direction as the direction of way placement, and allocates ways in the word direction in step S240 such that each way is constituted by a predetermined number of words. In the case of Nb being greater than Nw, the design support apparatus or the designer selects the bit direction as the direction of way placement, and allocates ways in the bit direction in step S250 such that each way is constituted by a predetermined number of bits.

In the case of one RAM macro having a size of 8K words and 54 bits, the design support apparatus and the designer selects the configuration in which 6 ways are allocated to one RAM macro in the bit direction (see FIG. 13).

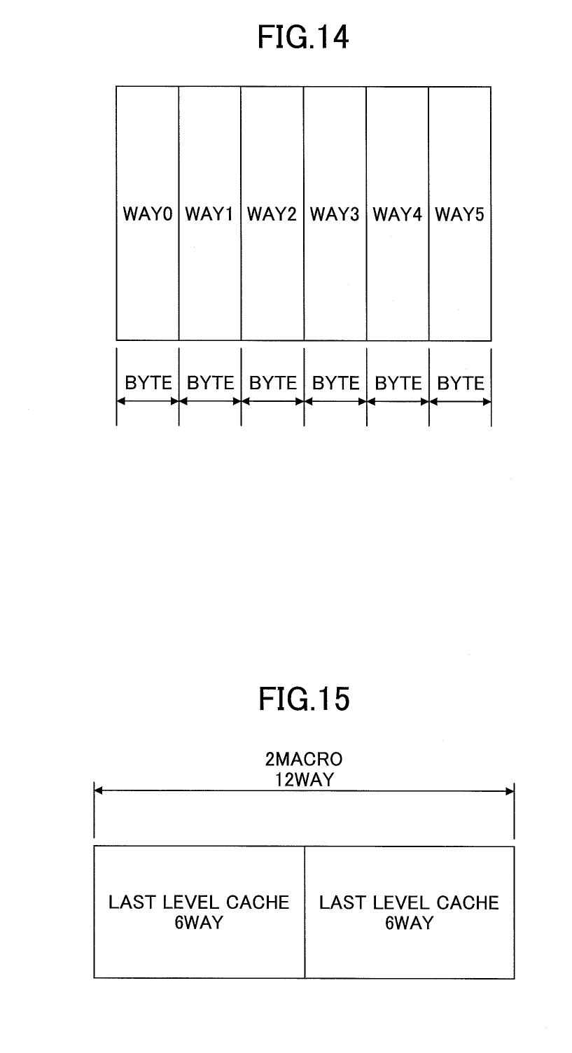

The check in step S200 illustrated in FIG. 9 may determine that the cache memory has a 12-way configuration. In such a case, 12 ways are achieved by use of 3 macros when allocating ways in the word direction (see FIG. 6). On the other hand, allocating 6 ways in the bit direction as illustrated in FIG. 14 results in the 12 ways being constituted by 2 macros (see FIG. 15) because one macro includes 6 ways.

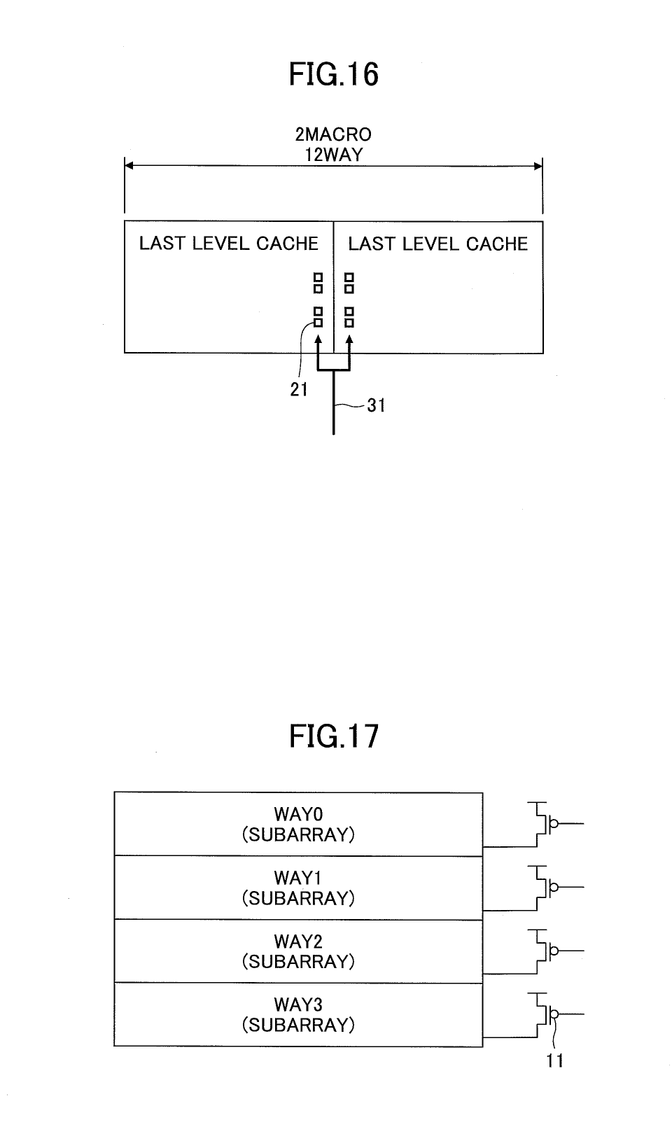

The 2 macros may be disposed side by side to constitute the 12 ways as illustrated in FIG. 16. Provision of cache memory terminals 21 close to an edge of each macro in this case eliminates the need for an interconnect line 31 to cross the border between the macros. This arrangement also reduces latency since available interconnect areas above the macros are broader. Further, spaces between macros for providing interconnect areas may be narrower or nonexistent, thereby achieving both an significant increase in implementation efficiency and a significant reduction in implementation cost.

### Formation of Power Blocking Switch

In the following, a description will be given of matters relating to the step of forming power supply blocking switches in step S110 illustrated in FIG. 2.

In step S110, switches are formed in the chip to suspend, on a way-specific basis, power supply to the ways arranged in the placement direction selected in step S100.

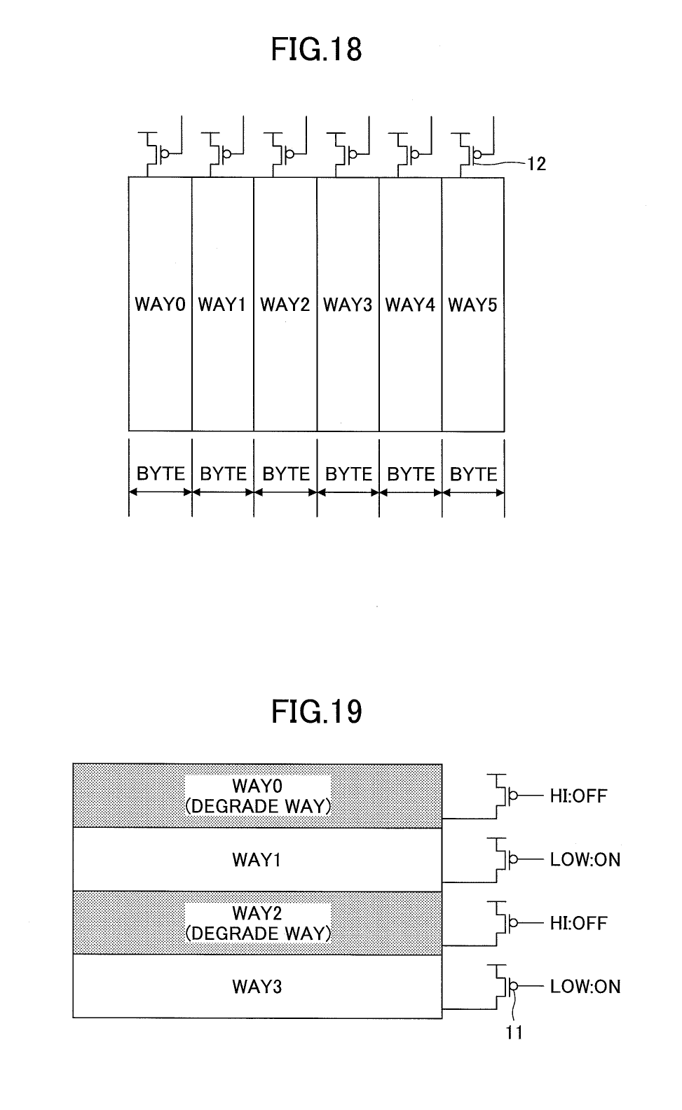

FIG. 17 is a drawing illustrating an example of a RAM macro in which switches 11 are disposed in one-to-one correspondence with ways arranged in the word direction in order to suspend power supply to the ways on a way-specific manner. FIG. 18 is a drawing illustrating an example of a RAM macro in which switches 12 are disposed in one-to-one correspondence with ways arranged in the bit direction in order to suspend power supply to the ways on a way-specific manner. The switches 11 and 12 are MOS (metal oxide semiconductor) transistors, for example. Although FIGS. 17 and 18 illustrate P-channel-type MOS transistors as examples, N-channel-type MOS transistors may alternatively be used.

### Power Supply Blocking Process

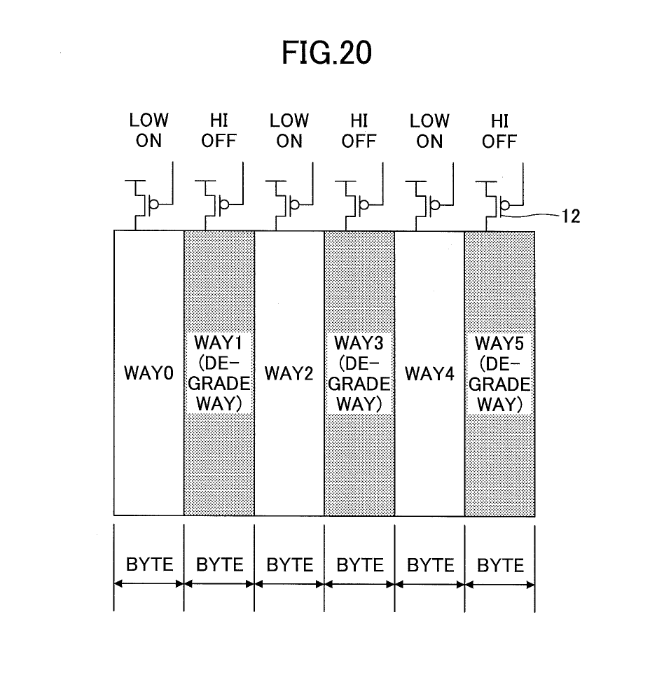

After the degeneration step of step S150 illustrated in FIG. 2, the power supply blocking step of step S160 is performed by the manufacturing apparatus. In the case of the ways being arranged next to one another in the word direction, as illustrated in FIG. 19, power supplied to the degenerated ways WAY0 and WAY2 is blocked by making nonconductive the switches 11 that are connected to the degenerated ways WAY0 and WAY2. In the case of the ways being arranged next to one another in the bit direction, as illustrated in FIG. 20, power supplied to the degenerated ways WAY1, WAY3, and WAY5 is blocked by making nonconductive the switches 12 that are connected to the degenerated ways WAY1, WAY3, and WAY5. Power supply is available to the ways that are connected to the switches 11 and 12 that are conductive.

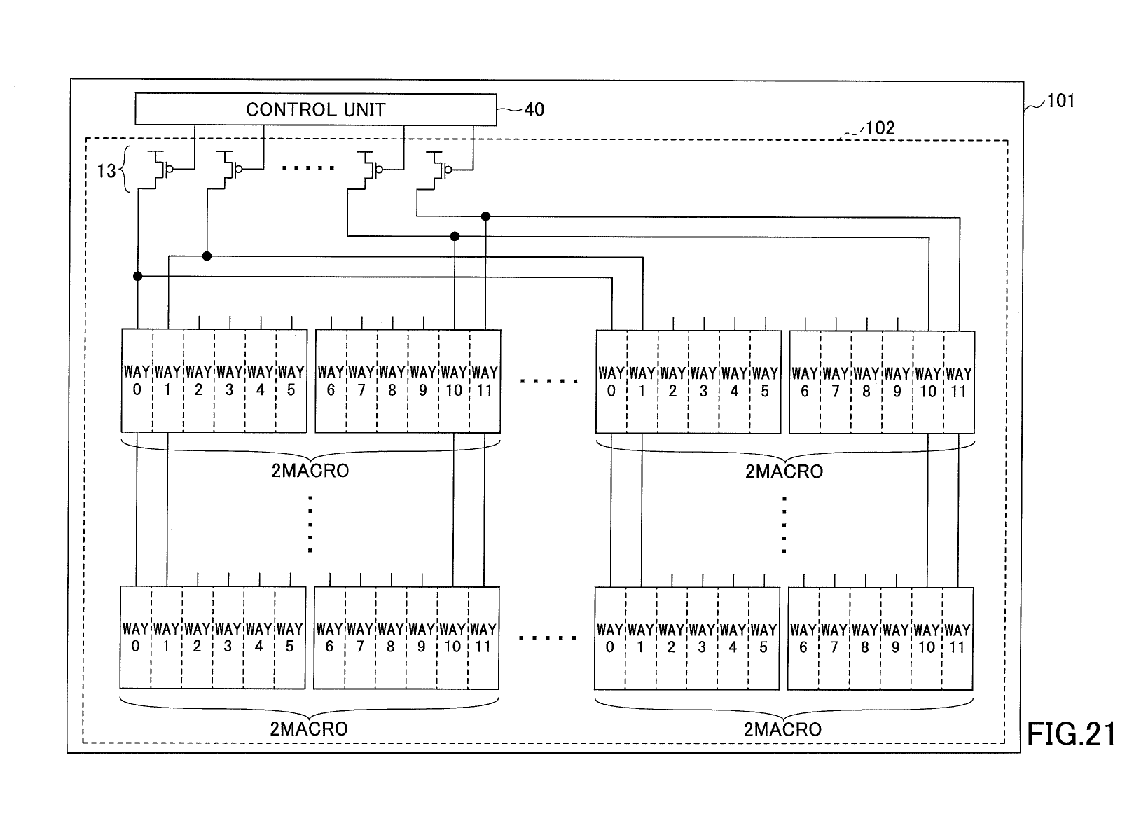

FIG. 21 is a drawing illustrating an example of the configuration of a chip 101 that includes a cache memory 102 and a control unit 40. The cache memory 102 is an example of a semiconductor memory device having a 12-way configuration that is implemented by use of 2 RAM macros. In the example illustrated in FIG. 21, the 12 ways WAY0 through WAY11 are allocated to each of the RAM macros in the bit direction. The cache memory 102 includes switches 13 that are used to suspend power supplied to the ways on a way-specific basis. The switches 13 are disposed in one-to-one correspondence with the ways, so that the total number of switches is 12, which is equal to the total number of ways. In this manner, the number of switches for use in power gating is set significantly lower than in the case in which power supply is suspended on a RAM-macro-specific basis.

The example illustrated in FIG. 21 is directed to a case in which ways are arranged in the bit direction. Alternatively, ways may be arranged in the word direction in the manner as previously described. In such a case also, the number of switches for suspending power supply on a way-specific basis is equal to the number of ways.

The control unit 40 is an example of a control unit that controls the switches 13 to suspend power supplied to the ways on a way-specific basis. Based on information indicative of the degenerated ways, for example, the control unit 40 turns off the switches 13 that are connected to the degenerated ways, thereby blocking power supply to the degenerated ways.

According to at least one embodiment, the number of switches for power gating is reduced.

Although a semiconductor memory device, a semiconductor integrated circuit and a method of making a semiconductor integrated circuit have been described with reference to the embodiments, the present invention is not limited to these embodiments. Various modifications and improvements such as combining an embodiment partially or entirely with one or more other embodiments or replacing part of an embodiment with part of another embodiment may be made without departing from the scope of the present invention.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A method of making a semiconductor integrated circuit, comprising forming switches configured to suspend, on a way-specific basis, power supply to ways allocated to one or more RAM macros.

2. The method as claimed in claim 1, wherein the ways are arranged next to one another in one of a word direction and a bit direction of the one or more RAM macros such that a number of ways allocated to each of the one or more RAM macros is larger than in a case in which the ways are arranged next to one another in another one of the word direction and the bit direction.

3. The method as claimed in claim 1, further comprising blocking, by use of the switches, power supply to one or more of the ways allocated to the one or more RAM macros.

4. The method as claimed in claim 3, further comprising degenerating one or more ways having one or more defective portions therein, wherein the one or more of the ways are the one or more degenerated ways.

5. A semiconductor memory device, comprising:
one or more RAM macros; and
switches configured to suspend, on a way-specific basis, power supply to ways allocated to the one or more RAM macros.

6. The semiconductor memory device as claimed in claim 5, wherein the ways are arranged next to one another in one of a word direction and a bit direction of the one or more RAM macros such that a number of ways allocated to each of the one or more RAM macros is larger than in a case in which the ways are arranged next to one another in another one of the word direction and the bit direction.

7. A semiconductor integrated circuit, comprising:
the semiconductor memory device of claim 5; and
a control unit configured to control the switches to suspend power supply to one or more of the ways allocated to the one or more RAM macros.

8. The semiconductor integrated circuit as claimed in claim 7, wherein the one or more of the ways are one or more degenerated ways having one or more defective portions therein in the one or more RAM macros.

9. A method of designing a semiconductor memory device, comprising:
selecting a word direction or a bit direction as a direction of placement in which ways allocated to one or more RAM macros are arranged next to one another; and
setting switches configured to suspend, on a way-specific basis, power supply to the ways that are arranged next to one another in the direction of placement.

10. The method as claimed in claim 9, wherein the selecting the word direction or the bit direction includes:
calculating a first way quantity that is a number of ways possibly arranged next to one another in the word direction in one RAM macro;
calculating a second way quantity that is a number of ways possibly arranged next to one another in the bit direction in one RAM macro;
comparing the first way quantity with the second way quantity; and
selecting, as the direction of placement, a direction that corresponds to a greater one of the first way quantity and the second way quantity.

11. The method as claimed in claim 10, wherein the calculating the first way quantity selects a way quantity for which a number of words per way becomes an integer, and the calculating the second way quantity selects a way quantity for which a number of bits per way becomes an integer.
